(19) United States
(12) Patent Application Publication
(10) Pub. No.: US 2025/0142796 A1
(43) Pub. Date: May 1, 2025

(54) MAGNETIC INTERFERENCE REDUCTION DEVICES AND SYSTEMS

(71) Applicant: Quantinuum LLC, Broomfield, CO (US)

(72) Inventors: Robert Daniel DELANEY, Denver, CO (US); Kyle Stephen MCKAY, Boulder, CO (US); William J. BAKER, Broomfield, CO (US)

(21) Appl. No.: 18/901,579

(22) Filed: Sep. 30, 2024

Related U.S. Application Data
(60) Provisional application No. 63/595,090, filed on Nov. 1, 2023.

(51) Int. Cl. H05K 9/00; G06N 10/40

(52) U.S. Cl. CPC H05K 9/0088; G06N 10/40; H05K 9/0075

(57) ABSTRACT

An interference reduction device is provided. The interference reduction device may include a magnetic shield positioned in proximity of a magnetic field. The magnetic shield is configured to reduce interference on the magnetic field along the direction of the magnetic field. The magnetic shield may include a cutout approximately parallel to the direction of the magnetic field, the cutout is configured to reduce a distortion caused by the magnetic shield on the magnetic field.

### CROSS-REFERENCE TO RELATED APPLICATION(S)

This application claims priority to U.S. Application No. 63/595,090, filed Nov. 1, 2024, the content of which is incorporated herein by reference in its entirety.

### TECHNICAL FIELD

Various embodiments relate to apparatuses, systems, and methods for magnetic interference reduction. Various embodiments relate to magnetic interference reduction in quantum processing systems.

### BACKGROUND

Quantum processors may use magnetic fields, for example static magnetic fields, for various operational purposes. In some applications, the magnetic field needs to be as uniform as possible and external interference on the magnetic field should be reduced. Through applied effort, ingenuity, and innovation many deficiencies of such prior magnetic interference reduction systems have been solved by developing solutions that are structured in accordance with the embodiments of the present invention, many examples of which are described in detail herein.

### BRIEF SUMMARY OF EXAMPLE EMBODIMENTS

Example embodiments provide magnetic interference reduction apparatus, systems, and methods. The magnetic interference reduction apparatus, systems, and methods may be used, for example, in a quantum apparatus.

According to a first aspect of the present disclosure, a quantum apparatus is provided. In an example embodiment, the quantum apparatus includes a magnetic field generator configured to generate a magnetic field in a magnetic field volume; and a magnetic interference reduction device. The magnetic interference reduction device includes a first magnetic shield. The first magnetic shield is a planar magnetic shield that is positioned in proximity of the magnetic field volume approximately parallel to a direction of the magnetic field. The first magnetic shield is configured to reduce interference on the magnetic field along the direction of the magnetic field.

In an example embodiment, the direction of the magnetic field is a quantization axis of the magnetic field volume.

In an example embodiment, the first magnetic shield comprises a cutout parallel to the direction of the magnetic field, the cutout is configured to reduce distortion caused by the first magnetic shield on the magnetic field.

In an example embodiment, the first magnetic shield comprises a continuous path of a high magnetic permeability material from a first edge of the planar magnetic shield to a second edge of the planar magnetic shield approximately in parallel to the direction of the magnetic field.

In an example embodiment, the quantum apparatus further includes a second magnetic shield, the second magnetic shield being a planar magnetic shield positioned in proximity of the magnetic field volume approximately in parallel to the direction of the magnetic field, wherein the second magnetic shield is configured to reduce interference on the magnetic field along the direction of the magnetic field.

In an example embodiment, a first plane of the first magnetic shield and a second plane of the second magnetic shield are approximately parallel.

In an example embodiment, the first magnetic shield comprises a cutout parallel to the direction of the magnetic field, the cutout is configured to reduce a distortion caused by the first magnetic shield on the magnetic field.

In an example embodiment, the second magnetic shield comprises a cutout parallel to the direction of the magnetic field, the cutout is configured to reduce a distortion caused by the second magnetic shield on the magnetic field.

According to another aspect of the present disclosure, a magnetic interference reduction device is provided. In an example embodiment, the magnetic interference reduction device includes a first magnetic shield. The first magnetic shield is a planar magnetic shield that is positioned approximately parallel to a direction of a magnetic field. The first magnetic shield is configured to reduce interference on the magnetic field along the direction of the magnetic field and the first magnetic shield comprises a cutout parallel to the direction of the magnetic field. The cutout is configured to reduce a distortion caused by the first magnetic shield on the magnetic field.

In an example embodiment, the first magnetic shield comprises a continuous path of a high magnetic permeability material from a first edge of the first magnetic shield to a second edge of the first magnetic shield approximately in parallel to the direction of the magnetic field.

In an example embodiment, the high magnetic permeability material comprises a mu-metal and/or a nickel-iron alloy.

In an example embodiment, the magnetic interference reduction device further includes a second magnetic shield that is a planar magnetic shield and that is positioned approximately in parallel to the direction of the magnetic field, wherein the second magnetic shield is configured to reduce interference on the magnetic field along the direction of the magnetic field.

In an example embodiment, the first magnetic shield and the second magnetic shield are approximately parallel.

In an example embodiment, the cutout of the first magnetic shield comprises a linear portion that is parallel to the direction of the magnetic field and that divides the first magnetic shield into a first portion and a second portion and the cutout further comprises an open area portion between the first portion and the second portion.

In an example embodiment, the second magnetic shield comprises a cutout parallel to the direction of the magnetic field, the cutout is configured to reduce a distortion caused by the second magnetic shield on the magnetic field.

In an example embodiment, the first magnetic shield comprises a first shielding layer comprising the high magnetic permeability material; a first foam layer covering the first shielding layer, the first foam layer configured to protect the first shielding layer by absorbing shock; and a first metal layer configured to protect the first shielding layer; and the second magnetic shield comprises a second shielding layer; a second foam layer covering the second shielding layer, the second foam layer configured to protect the second shielding layer by absorbing shock; and a second metal layer configured to protect the second foam layer.

According to another aspect of the present disclosure, a magnetic interference reduction device is provided. In an example embodiment, the magnetic interference reduction device includes one or more magnetic elements configured to generate a magnetic field; a first planar magnetic shield positioned parallel to a direction of the magnetic field; and a second planar magnetic shield positioned parallel to the direction of the magnetic field. The first planar magnetic shield and the second planar magnetic shield are configured to reduce interference on the magnetic field along the direction of the magnetic field.

In an example embodiment, the first planar magnetic shield comprises a first cutout parallel to the direction of the magnetic field, the first cutout configured to reduce distortion caused by the first planar magnetic shield on the magnetic field; and the second planar magnetic shield comprises a second cutout parallel to the direction of the magnetic field, the second cutout configured to reduce distortion caused by the second planar magnetic shield on the magnetic field.

In an example embodiment, the first planar magnetic shield comprises a first continuous path of a high magnetic permeability material from a first edge of the first planar magnetic shield to a second edge of the first planar magnetic shield approximately in parallel to the direction of the magnetic field; and the second planar magnetic shield comprises a second continuous path of a high magnetic permeability material from a first edge of the second planar magnetic shield to a second edge of the second planar magnetic shield approximately in parallel to the direction of the magnetic field.

In an example embodiment, the first planar magnetic shield comprises a first shielding layer comprising a high magnetic permeability material; a first foam layer covering the first shielding layer, the first foam layer configured to protect the first shielding layer by absorbing shock; and a first metal layer configured to protect the first foam layer; and the second planar magnetic shield comprises: a second shielding layer; a second foam layer covering the second shielding layer, the second foam layer configured to protect the second shielding layer by absorbing shock; and a second metal layer configured to protect the second foam layer.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a schematic diagram illustrating an example magnetic shield, according to an example embodiment.

FIGS. 2A-2B are schematic diagrams illustrating example magnetic shields, according to various example embodiments.

FIG. 3 is a schematic diagram illustrating an example magnetic shield, according to an example embodiment.

FIG. 4 is a schematic diagram illustrating an example magnetic shield, according to an example embodiment.

FIG. 5 is a schematic diagram illustrating example magnetic shields, according to an example embodiment.

FIG. 6 is a schematic diagram illustrating various components of a quantum apparatus, according to an example embodiment.

FIG. 7 is a schematic diagram illustrating an example magnetic shield, according to an example embodiment.

FIG. 8 is a schematic diagram illustrating a cross sectional view of an example magnetic shield, according to an example embodiment.

FIG. 9 is a schematic diagram illustrating an example quantum computing system comprising a planar magnetic shield, according to an example embodiment.

FIG. 10 provides a schematic diagram of an example controller of a quantum computer, according to various embodiments.

FIG. 11 provides a schematic diagram of an example computing entity of a quantum computer system that may be used in accordance with an example embodiment.

### DETAILED DESCRIPTION OF SOME EXAMPLE EMBODIMENTS

The present invention now will be described more fully hereinafter with reference to the accompanying drawings, in which some, but not all embodiments of the invention are shown.

Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally” and “approximately” refer to within engineering and/or manufacturing limits and/or within user measurement capabilities, unless otherwise indicated. Like numbers refer to like elements throughout.

Various embodiments of the present disclosure provide a device for reducing magnetic field interference on a magnetic field. The magnetic field may be a static magnetic field or include a static magnetic field component. For example, a quantum processor may use static magnetic fields for quantum gates, cooling of the motional modes of the quantum objects, or readout/measurement of our qubit states. Therefore, there may be a need for using magnetic fields and protecting the magnetic field against interference in quantum processors. Various embodiments may protect a static magnetic field used in penning traps against interference. In penning traps, static magnetic fields (in combination with static electric fields), may be used to trap a quantum object.

The device for reducing magnetic field interference includes a magnetic shield, in various embodiments. For example, in various embodiments a desired magnetic field is generated within a volume and the magnetic shield is configured to reduce interference, within the volume, by external magnetic fields. In various embodiments, a system such as an experiment system and/or controlled quantum state evolution system is performed within the volume.

Conventionally, magnetic shields may be used to surround and/or enclose a volume containing the system (e.g., experiment system, controlled quantum state evolution system, and/or the like) in a high magnetic permeability material. However, such an approach may be costly, add to the weight and volume of the system, and may highly distort the magnetic field that needs to be protected. Moreover, such an approach reduces access to the volume and the system disposed therein. For example, providing optical and/or electrical signals to the volume and the system disposed therein is complicated by the volume being surrounded and/or enclosed by the shielding material. Alignment of provided optical signals with target locations and/or optical elements of the system are also complicated by the volume being surrounded and/or enclosed by the shielding material.

The system (e.g., experiment system, controlled quantum state evolution system, and/or the like) using the magnetic field (for example a static magnetic field) may be sensitive to interference along a specific direction. For example, in quantum computers in which the qubits are at least partially defined by a quantization axis of a magnetic field, the system may be sensitive to magnetic field interference along the quantization axis. However, such a system may be significantly less sensitive to magnetic field interference in directions other than quantization axis. For example, such a system may be, at least to first order, not sensitive to magnetic field interference in directions other than the quantization axis. In various embodiments, the system includes a magnetic field generator configured to generate a desired magnetic field in the direction of the quantization axis within the volume. For example, in various embodiments, the magnetic field generator (e.g., a pair of Helmholtz coils, set of permanent magnets, etc.,) is configured to generate a desired magnetic field in a quantization axis direction that is applied to the quantum objects (e.g., atom, ion, molecule, quantum particle, quantum dot, and/or the like) confined by a quantum object trap. Various embodiments of the present disclosure therefore provide reduction in magnetic field interference in the direction of the quantization axis within a volume.

It is further desirable to lower a distortion that may be caused by the magnetic shield on the desired magnetic field. For example, the system (e.g., experiment system, controlled quantum state evolution system) is configured to operate with a desired magnetic field in the direction of a quantization axis. Thus, distortion to the desired magnetic field may cause various errors in the functioning of the system. Various embodiments of the present disclosure reduce distortion caused by the magnetic shield on the desired magnetic field.

### Exemplary Magnetic Interference Reduction Device

Referring now to FIG. 1 a schematic diagram illustrating magnetic interference reduction device 100 is provided in accordance with various embodiments of the present disclosure. In various embodiments, the magnetic interference reduction device 100 includes a magnetic shield 105. In various embodiments, the magnetic shield 105 is a planar magnetic shield. In various embodiments, the magnetic shield 105 may be nearly planar. In various embodiments, the magnetic shield 105 may not be planar. The magnetic shield 105 includes a first section 102 and a second section 104, in the illustrated embodiment. The magnetic shield may be positioned approximately parallel to a direction of a magnetic field 110. The magnetic field may be produced by a pair of magnets, for example magnet 112 and magnet 114. The magnets may be permanent magnets or magnetic coils (e.g., Helmholtz coils and/or the like). In various embodiments, the magnetic field may be produces using any number of magnetic elements that may include any of permanent magnets and/or magnetic coils.

In various embodiments, the magnetic shield may include a cutout 106 parallel to the direction of the magnetic field 110. In various embodiments, the magnetic shield is configured to reduce interference on the magnetic field along the direction of the magnetic field 110 while reduce distortion caused by the magnetic shield on the magnetic field 110. By providing a cutout in parallel and/or adjacent to the direction of magnetic field 110, a distortion caused by the magnetic shield in the magnetic field 110 is reduced. In various embodiments, the cutout 106 is configured to reduce a distortion caused by the magnetic shield on the magnetic field 110. For example, the cutout 106 may decrease the amount of the magnetic field 110 that is drawn into the magnetic shield 105, thus reducing the distortion.

In various embodiments, the magnetic interference reduction device 100 may comprise a single section without any cutout. For example, a magnetic field reduction that comprises a single section may provide for increased simplicity and reduced manufacturing costs.

In various embodiments, the magnetic shield may include a continuous path of a high magnetic permeability material from a first edge of the magnetic shield to a second edge of the magnetic shield approximately in parallel to the direction of the magnetic field. For example, the first or second sections of the magnetic shield each include a continuous path of a high magnetic permeability material from an edge closer to the magnet 114 to the edge closer to the magnet 112. In various embodiments, the high magnetic permeability material has a magnetic permeability of at least 70,000, at least 80,000, or at least 90,000.

Therefore, in various embodiments, the magnetic shield does not include any edge-to-edge cutouts in a direction that crosses the direction of a magnetic field 110 such that the cutout would prevent a continuous path of a high magnetic permeability material from an edge closer to the magnet 114 to the edge closer to the magnet 112. In example embodiments, the interference magnetic field lines may be redirected into the material rather than the volume of the magnetic field 110 that is being shielded. In some examples, the high magnetic permeability material includes a mu-metal layer and/or a nickel-iron alloy. For example, in a cryogenic environment, a nickel-iron alloy other than a mu-metal may be used.

In various embodiments, the first or second sections of the magnetic shield may have any geometrical shapes. For example, FIG. 2A illustrates a circular shape for the first section 202 and the second section 204 of the magnetic shield 200. For example, FIG. 2B illustrates a triangular shape for the first section 252 and the second section 254 of the magnetic shield 250. In various embodiments, any other geometrical shapes for the first and second sections of the magnetic shield may be used. In various embodiments, the first and second sections of the magnetic shield may have different geometrical shapes. Both the magnetic shield 200 and the magnetic shield 250 include linear cutouts.

Referring now to FIG. 3 a schematic diagram illustrating a magnetic shield 300 is provided in accordance with various embodiments of the present disclosure. The magnetic shield 300 includes a cutout that includes a linear portion and an open area portion. For example, in certain embodiments, the magnetic shield includes an open area 350 between the first section 302 and the second section 304 of the magnetic shield 300. The open area 350 may provide for space to place various sub-systems or components using the magnetic field 110.

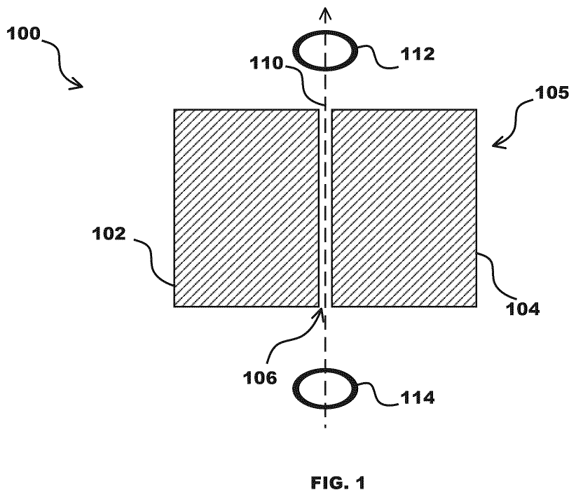

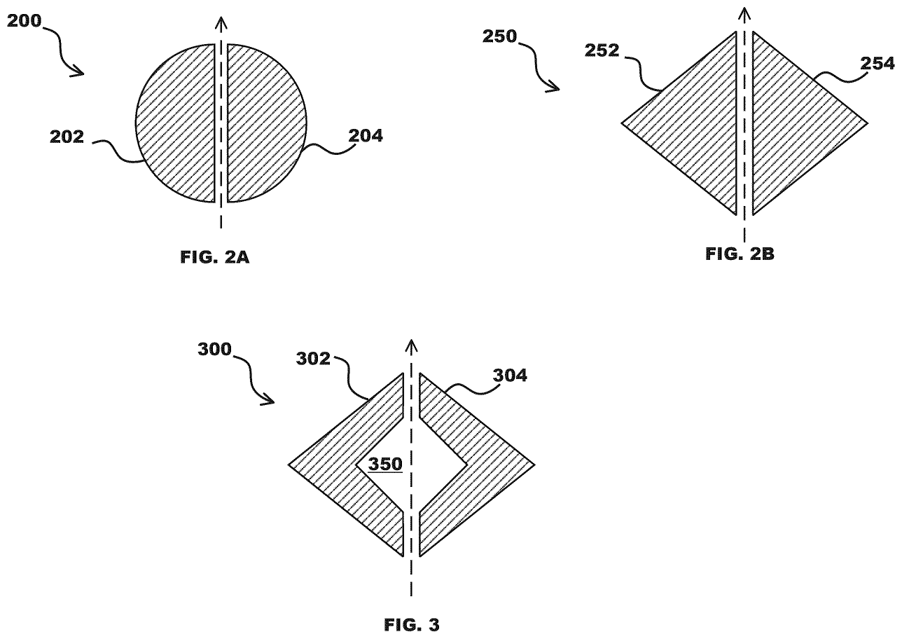

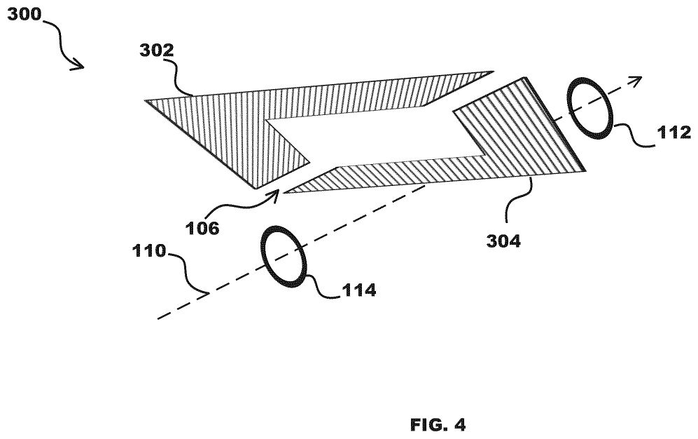

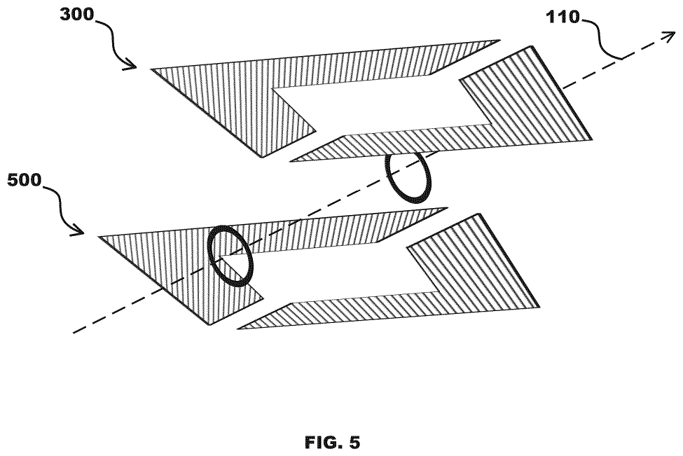

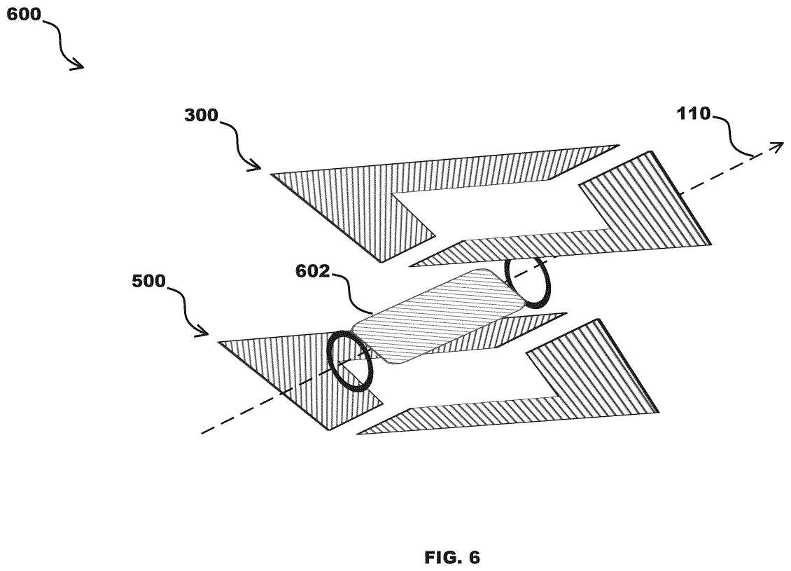

In various embodiments, the magnetic shield may be placed in the same plane or in an adjacent plane to the magnetic field 110. For example, as illustrated by FIG. 4, the magnetic shield 300 may be placed in an offset plane with respect to the magnetic field 110. In various embodiments, the cutout 106 may remain approximately parallel to the direction of the magnetic field 110.

Referring now to FIG. 5 a schematic diagram illustrating a magnetic interference reduction device that includes multiple magnetic shields is provided in accordance with various embodiments of the present disclosure. In various embodiments, the magnetic interference reduction includes the first magnetic shield 300 and a second magnetic shield 500. The second magnetic shield 500 may be approximately parallel to the direction of the magnetic field 110 and/or approximately parallel to the first magnetic shield 300.

In various embodiments, the magnetic interference reduction device may have one or more magnetic shields. In the example illustrated in FIG. 5, the magnetic interference reduction device has two magnetic shields 300 and 500, however in other examples more magnetic shields such as three, four, five, etc. may be used. In example embodiments the other planar magnetic shield(s) are configured to reduce interference on the magnetic field along the direction of the magnetic field. In various embodiments, the magnetic shields may be approximately parallel to each other and/or the magnetic field 110. In various embodiments, the magnetic shields may not be parallel to each other and/or the magnetic field 110 and may be oriented at various angles. In example embodiments, the magnetic shields may be more effective in reducing the interference when they are approximately in parallel with each other and/or with the magnetic field 110.

In various embodiments, various magnetic shields may have the same or different overall geometrical shapes or different geometrical shapes of each section of the magnetic shield. In various embodiments, some of the magnetic shields may not have the cutout. For example, some of the magnetic shields that are placed further away from the magnetic fields 110 may not need the cutout because they may cause less distortion on the magnetic field 110.

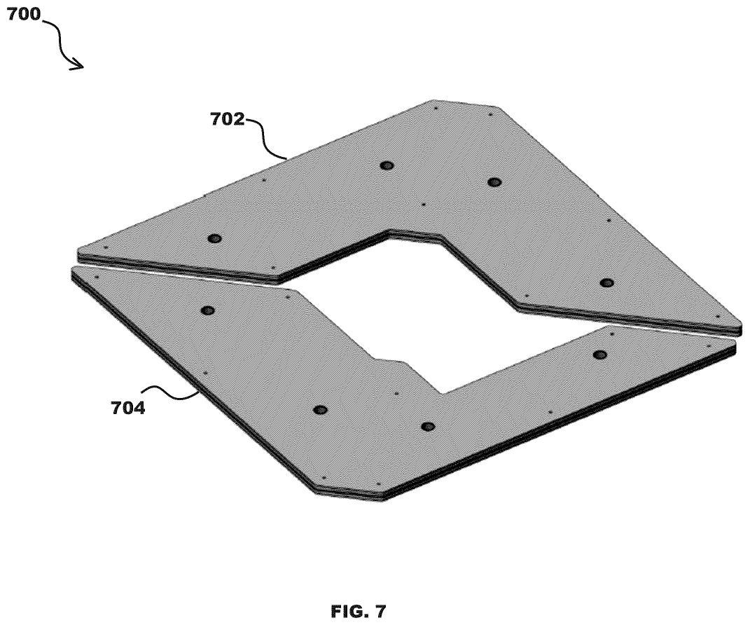

Referring now to FIG. 6 a schematic diagram illustrating various aspects of a quantum apparatus 600 is provided in accordance with various embodiments of the present disclosure. In various embodiments, the quantum apparatus 600 includes a quantum object trap 602. The quantum object trap 602 may be configured to trap a quantum object using a magnetic field 110.

In various embodiments, the quantum apparatus 600 may include a planar magnetic shield positioned in proximity of the quantum object trap 602 approximately parallel to a direction of the magnetic field 110. In various embodiments, the planar magnetic shield is configured to reduce interference on the magnetic field 110 along the direction of the magnetic field. In various embodiments, the direction of the magnetic field is the quantization axis of the quantum object trap 602.

In various embodiments, the quantum apparatus 600 may include one or more planar magnetic shields. For example, as shown in FIG. 6, the quantum apparatus 600 may include first magnetic shield 300 and second magnetic shield 500. In various embodiments, the planar magnetic shield(s) may be similar to and have similar function(s) with respect to the magnetic field 110 as any of the magnetic shield(s) described herein, for example as described with reference to FIGS. 1-5.

Referring now to FIG. 7 a schematic diagram illustrating a magnetic shield 700 is provided in accordance with various embodiments of the present disclosure. In various embodiments, a first section 702 of the magnetic field may have a different shape than the second section 704 of the magnetic shield. Each section may have variously shaped edges and/or various holes for manufacturing, mounting, or assembly purposes as for example illustrated by FIG. 7.

Referring to FIGS. 1-7, any of magnetic field reduction devices described above may comprise a single section without any cutout. Doing so may for example increase simplicity and reduce manufacturing costs.

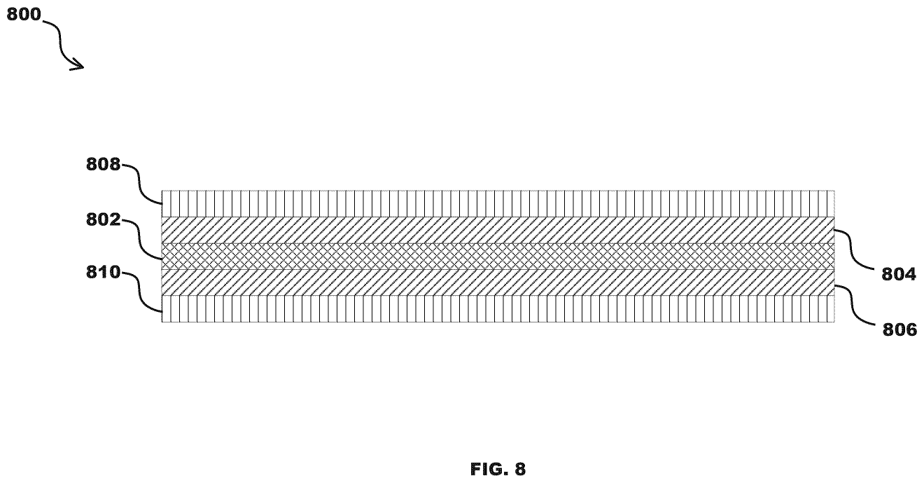

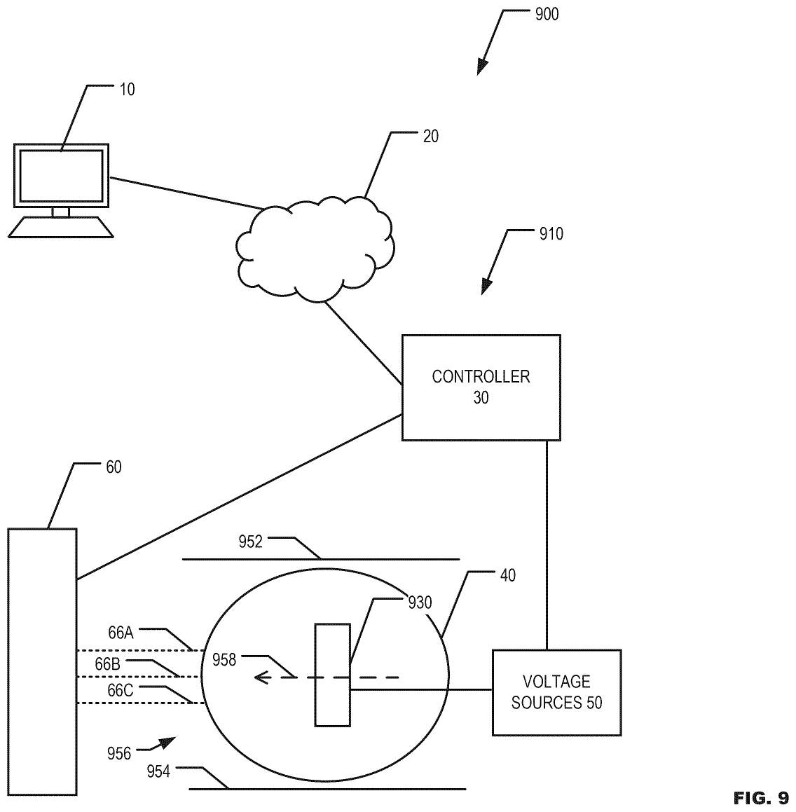

Referring now to FIG. 8 a schematic diagram illustrating an intersection 800 of a planar magnetic shield (e.g., a cross-section of a portion of first magnetic shield 952 and/or second magnetic shield 954, as shown in FIG. 9) is provided in accordance with various embodiments of the present disclosure. In various embodiments, the planar magnetic shield includes a shielding layer 802, a first foam layer 804 and a first metal layer 808. In various embodiments, the shielding layer comprises a high magnetic permeability material such as mu-metal and/or a nickel-iron alloy, for example. In various embodiments, the planar magnetic shield may include a second foam layer 806 and a second metal layer 810. In an example, the metal layers 808 and 810 may include aluminum.

In example embodiments, the foam layer(s) are configured to protect the shielding layer 802 by absorbing shock. In example embodiments, the metal layers are configured to protect the shielding layer 802, and to provide rigidity to the shielding structure.

### Exemplary Quantum Computing System Comprising a Quantum Object Confinement Apparatus

In an example embodiment, the system is a controlled quantum evolution system such as a quantum charge-coupled device (QCCD)-based quantum computer. FIG. 9 provides a schematic diagram of an example quantum computing system 900 comprising a quantum object confinement apparatus 930 (e.g., a quantum object trap and/or the like), in accordance with an example embodiment.

In various embodiments, the quantum computing system 900 comprises a computing entity 10 and a quantum computer 910. In various embodiments, the quantum computer 910 comprises a controller 30, a cryostat and/or vacuum chamber 40 enclosing a confinement apparatus 930 (e.g., a quantum object trap), and one or more manipulation sources 60. In various embodiments, with reference to FIG. 9, the vacuum chamber 40 and/or the confinement apparatus 930 (e.g., a quantum object trap) are included in the quantum apparatus 600. For example, the cryostat and/or vacuum chamber 40 may be a pressure-controlled chamber. In an example embodiment, the manipulation signals generated by the manipulation sources 60 are provided to the interior of the cryostat and/or vacuum chamber 40 (where the quantum object confinement apparatus 930 is located) via corresponding optical paths 66 (e.g., 66A, 66B, 66C). In an example embodiment, the one or more manipulation sources 60 may comprise one or more lasers (e.g., optical lasers, microwave sources, and/or the like). In various embodiments, each manipulation source 60 is configured to generate a manipulation signal having a respective characteristic wavelength in the microwave, infrared, visible, or ultraviolet portion of the electromagnetic spectrum. In various embodiments, the one or more manipulation sources 60 are configured to manipulate and/or cause a controlled quantum state evolution of one or more quantum objects within the confinement apparatus. For example, in an example embodiment, wherein the one or more manipulation sources 60 comprise one or more lasers, the lasers may provide one or more laser beams to quantum objects trapped within the confinement apparatus 930 within the cryostat and/or vacuum chamber 40. For example, the manipulation sources 60 may be configured to generate one or more beams that may be used to initialize an quantum object into a state of a qubit space such that the quantum object may be used as a qubit of the quantum computer, perform one or more gates on one or more qubits of the quantum computer, read and/or determine a state of one or more qubits of the quantum computer, and/or the like.

In various embodiments, the quantum computer 910 includes first and second magnetic shields 952 and 954. The first and second magnetic shields 952 and 954 may be configured to reduce magnetic field interference in the direction of a quantization axis 958 within a volume 956. While reducing the magnetic field interference, the first and second magnetic shields 952 and 954 allow access for providing optical signals (e.g., from manipulation sources 60) and/or electrical signals (e.g., from voltage source 50) to the volume to the volume 956.

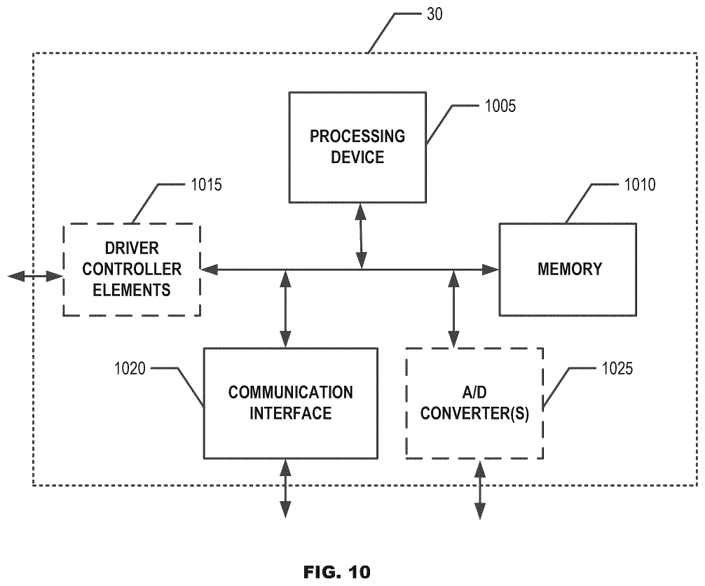

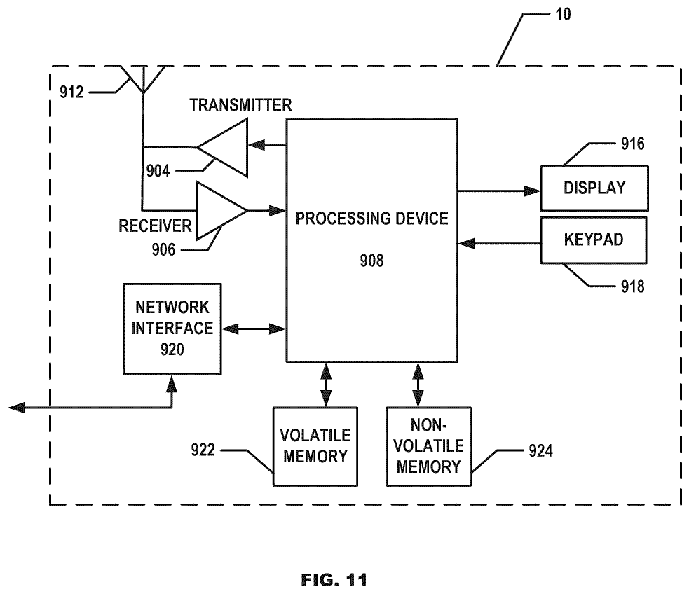

In various embodiments, the quantum computer 910 comprises an optics collection system configured to collect and/or detect photons generated by qubits (e.g., during reading procedures). The optics collection system may comprise one or more optical elements (e.g., lenses, mirrors, waveguides, fiber optics cables, and/or the like) and one or more photodetectors. In various embodiments, the photodetectors may be photodiodes, photomultipliers, charge-coupled device (CCD) sensors, complementary metal oxide semiconductor (CMOS) sensors, Micro-Electro-Mechanical Systems (MEMS) sensors, and/or other photodetectors that are sensitive to light at an expected fluorescence wavelength of the qubits of the quantum computer. In various embodiments, the detectors may be in electronic communication with the controller 30 via one or more A/D converters 1025 (see FIG. 10) and/or the like.

In various embodiments, the quantum computer 910 comprises one or more voltage sources 50. For example, the voltage sources 50 may comprise a plurality of voltage drivers and/or voltage sources and/or at least one RF driver and/or voltage source. The voltage sources 50 may be electrically coupled to the corresponding potential generating elements (e.g., electrodes) of the confinement apparatus 930, in an example embodiment.

In various embodiments, a computing entity 10 is configured to allow a user to provide input to the quantum computer 910 (e.g., via a user interface of the computing entity 10) and receive, view, and/or the like output from the quantum computer 910. The computing entity 10 may be in communication with the controller 30 of the quantum computer 910 via one or more wired or wireless networks 20 and/or via direct wired and/or wireless communications. In an example embodiment, the computing entity 10 may translate, configure, format, and/or the like information/data, quantum computing algorithms and/or circuits, and/or the like into a computing language, executable instructions, command sets, and/or the like that the controller 30 can understand and/or implement.

In various embodiments, the controller 30 is configured to control the voltage sources 50, cryostat system and/or vacuum system controlling the temperature and pressure within the cryostat and/or vacuum chamber 40, manipulation sources 60, and/or other systems controlling various environmental conditions (e.g., temperature, pressure, and/or the like) within the cryostat and/or vacuum chamber 40 and/or configured to manipulate and/or cause a controlled evolution of quantum states of one or more quantum objects within the confinement apparatus. For example, the controller 30 may cause a controlled evolution of quantum states of one or more quantum objects within the confinement apparatus to execute a quantum circuit and/or algorithm. For example, the controller 30 may cause a reading procedure comprising coherent shelving to be performed, possibly as part of executing a quantum circuit and/or algorithm. In various embodiments, the quantum objects confined within the confinement apparatus are used as qubits of the quantum computer 910.

### Exemplary Controller

In various embodiments, a quantum object confinement apparatus 930 is incorporated into a system (e.g., a quantum computer 910) comprising a controller 30. In various embodiments, the controller 30 is configured to control various elements of the system (e.g., quantum computer 910). For example, the controller 30 may be configured to control the voltage sources 50, a cryostat system and/or vacuum system controlling the temperature and pressure within the cryostat and/or vacuum chamber 40, manipulation sources 60, cooling system, and/or other systems controlling the environmental conditions (e.g., temperature, humidity, pressure, and/or the like) within the cryostat and/or vacuum chamber 40 and/or configured to manipulate and/or cause a controlled evolution of quantum states of one or more quantum objects confined by the quantum object confinement apparatus 930. In various embodiments, the controller 30 may be configured to receive signals from one or more optics collection systems.

As shown in FIG. 10, in various embodiments, the controller 30 may comprise various controller elements including processing elements 1005, memory 1010, driver controller elements 1015, a communication interface 1020, analog-digital converter elements 1025, and/or the like. For example, the processing elements 1005 may comprise programmable logic devices (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like. and/or controllers. The term circuitry may refer to an entirely hardware embodiment or a combination of hardware and computer program products. In an example embodiment, the processing element 1005 of the controller 30 comprises a clock and/or is in communication with a clock.

For example, the memory 1010 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FeRAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In various embodiments, the memory 1010 may store a queue of commands to be executed to cause a quantum algorithm and/or circuit to be executed (e.g., an executable queue), qubit records corresponding the qubits of quantum computer (e.g., in a qubit record data store, qubit record database, qubit record table, and/or the like), a calibration table, computer program code (e.g., in a one or more computer languages, specialized controller language(s), and/or the like), and/or the like. In an example embodiment, execution of at least a portion of the computer program code stored in the memory 1010 (e.g., by a processing element 1005) causes the controller 30 to perform one or more steps, operations, processes, procedures and/or the like described herein for providing manipulation signals to quantum object locations and/or collecting, detecting, capturing, and/or measuring indications of emitted signals emitted by quantum objects located at corresponding quantum object locations of the quantum object confinement apparatus 930.

In various embodiments, the driver controller elements 1015 may include one or more drivers and/or controller elements each configured to control one or more drivers. In various embodiments, the driver controller elements 1015 may comprise drivers and/or driver controllers. For example, the driver controllers may be configured to cause one or more corresponding drivers to be operated in accordance with executable instructions, commands, and/or the like scheduled and executed by the controller 30 (e.g., by the processing element 1005). In various embodiments, the driver controller elements 1015 may enable the controller 30 to operate a voltage sources 50, manipulation sources 60, cooling system, and/or the like. In various embodiments, the drivers may be laser drivers configured to operate one or manipulation sources 60 to generate manipulation signals; vacuum component drivers; drivers for controlling the flow of current and/or voltage applied to electrodes used for maintaining and/or controlling the trapping potential of the quantum object confinement apparatus 930 (and/or other drivers for providing driver action sequences to potential generating elements of the quantum object confinement apparatus); cryostat and/or vacuum system component drivers; cooling system drivers, and/or the like. In various embodiments, the controller 30 comprises means for communicating and/or receiving signals from one or more optical receiver components (e.g., photodetectors of the optics collection system). For example, the controller 30 may comprise one or more analog-digital converter elements 1025 configured to receive signals from one or more optical receiver components (e.g., a photodetector of the optics collection system), calibration sensors, and/or the like.

In various embodiments, the controller 30 may comprise a communication interface 1020 for interfacing and/or communicating with a computing entity 10. For example, the controller 30 may comprise a communication interface 1020 for receiving executable instructions, command sets, and/or the like from the computing entity 10 and providing output received from the quantum computer 910 (e.g., from an optical collection system) and/or the result of a processing the output to the computing entity 10. In various embodiments, the computing entity 10 and the controller 30 may communicate via a direct wired and/or wireless connection and/or via one or more wired and/or wireless networks 20.

### Exemplary Computing Entity

FIG. 11 provides an illustrative schematic representative of an example computing entity 10 that can be used in conjunction with embodiments of the present invention. In various embodiments, a computing entity 10 is configured to allow a user to provide input to the quantum computer 910 (e.g., via a user interface of the computing entity 10) and receive, display, analyze, and/or the like output from the quantum computer 910.

As shown in FIG. 11, a computing entity 10 can include an antenna 912, a transmitter 904 (e.g., radio), a receiver 906 (e.g., radio), and a processing element 908 that provides signals to and receives signals from the transmitter 904 and receiver 906, respectively. The signals provided to and received from the transmitter 904 and the receiver 906, respectively, may include signaling information/data in accordance with an air interface standard of applicable wireless systems to communicate with various entities, such as a controller 30, other computing entities 10, and/or the like. In this regard, the computing entity 10 may be capable of operating with one or more air interface standards, communication protocols, modulation types, and access types. For example, the computing entity 10 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 10 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1X (1xRTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing entity 10 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 10 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 10 can also download changes, add-ons, and updates, for instance, to its firmware, software (e.g., including executable instructions, applications, program modules), and operating system.

The computing entity 10 may also comprise a user interface device comprising one or more user input/output interfaces (e.g., a display 916 and/or speaker/speaker driver coupled to a processing element 908 and a touch screen, keyboard, mouse, and/or microphone coupled to a processing element 908). For instance, the user output interface may be configured to provide an application, browser, user interface, interface, dashboard, screen, webpage, page, and/or similar words used herein interchangeably executing on and/or accessible via the computing entity 10 to cause display or audible presentation of information/data and for interaction therewith via one or more user input interfaces. The user input interface can comprise any of a number of devices allowing the computing entity 10 to receive data, such as a keypad 918 (hard or soft), a touch display, voice/speech or motion interfaces, scanners, readers, or other input device. In embodiments including a keypad 918, the keypad 918 can include (or cause display of) the conventional numeric (0-9) and related keys (#, *), and other keys used for operating the computing entity 10 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 10 can collect information/data, user interaction/input, and/or the like.

The computing entity 10 can also include volatile storage or memory 922 and/or non-volatile storage or memory 924, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 10.

### Technical Advantages

Conventionally, magnetic shields may be used to surround and/or enclose a volume containing the system (e.g., experiment system, controlled quantum state evolution system, and/or the like) in a high magnetic permeability material. However, such an approach may be costly, add to the weight and volume of the system, and may highly distort the magnetic field that needs to be protected. Moreover, such an approach reduces access to the volume and the system disposed therein. For example, providing optical and/or electrical signals to the volume and the system disposed therein is complicated by the volume being surrounded and/or enclosed by the shielding material. Alignment of provided optical signals with target locations and/or optical elements of the system are also complicated by the volume being surrounded and/or enclosed by the shielding material.

The system (e.g., experiment system, controlled quantum state evolution system, and/or the like) using the magnetic field may be sensitive to interference along a specific direction. For example, in quantum computers in which the qubits are at least partially defined by a quantization axis of a magnetic field, the system may be sensitive to magnetic field interference along the quantization axis. However, such a system may be significantly less sensitive to magnetic field interference in directions other than quantization axis. For example, such a system may be, at least to first order, not sensitive to magnetic field interference in directions other than the quantization axis. In various embodiments, the system includes a magnetic field generator configured to generate a desired magnetic field in the direction of the quantization axis within the volume. For example, in various embodiments, the magnetic field generator (e.g., a pair of Helmholtz coils, set of permanent magnets, etc.) is configured to generate a desired magnetic field in a quantization axis direction that is applied to the quantum objects confined by a quantum object trap. Various embodiments of the present disclosure therefore provide reduction in magnetic field interference in the direction of the quantization axis within a volume.

It is further desirable to lower a distortion that may be caused by the magnetic shield on the desired magnetic field. For example, the system (e.g., experiment system, controlled quantum state evolution system) is configured to operate with a desired magnetic field in the direction of a quantization axis. Thus, distortion to the desired magnetic field may cause various errors in the functioning of the system. Various embodiments of the present disclosure reduce distortion caused by the magnetic shield on the desired magnetic field.

### Conclusion

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

1. A quantum apparatus comprising:
a magnetic field generator configured to generate a magnetic field in a magnetic field volume; and
a first magnetic shield, wherein the first magnetic shield is a planar magnetic shield and is positioned in proximity of the magnetic field volume approximately parallel to a direction of the magnetic field, wherein the first magnetic shield is configured to reduce interference on the magnetic field along the direction of the magnetic field.

2. The quantum apparatus of claim 1, wherein the direction of the magnetic field is a quantization axis of the magnetic field volume.

3. The quantum apparatus of claim 1, wherein the first magnetic shield comprises a cutout parallel to the direction of the magnetic field, the cutout is configured to reduce distortion caused by the first magnetic shield on the magnetic field.

4. The quantum apparatus of claim 3, wherein the first magnetic shield comprises a continuous path of a high magnetic permeability material from a first edge of the planar magnetic shield to a second edge of the planar magnetic shield approximately in parallel to the direction of the magnetic field.

5. The quantum apparatus of claim 1, comprising a second magnetic shield, the second magnetic shield being a planar magnetic shield positioned in proximity of the magnetic field volume approximately in parallel to the direction of the magnetic field, wherein the second magnetic shield is configured to reduce interference on the magnetic field along the direction of the magnetic field.

6. The quantum apparatus of claim 5, wherein a first plane of the first magnetic shield and a second plane of the second magnetic shield are approximately parallel.

7. The quantum apparatus of claim 5, wherein the first magnetic shield comprises a cutout parallel to the direction of the magnetic field, the cutout is configured to reduce a distortion caused by the first magnetic shield on the magnetic field.

8. The quantum apparatus of claim 5, wherein the second magnetic shield comprises a cutout parallel to the direction of the magnetic field, the cutout is configured to reduce a distortion caused by the second magnetic shield on the magnetic field.

9. A magnetic interference reduction device comprising a first magnetic shield, the first magnetic shield being a planar magnetic shield that is positioned approximately parallel to a direction of a magnetic field, wherein the first magnetic shield is configured to reduce interference on the magnetic field along the direction of the magnetic field and the first magnetic shield comprises a cutout parallel to the direction of the magnetic field, the cutout is configured to reduce a distortion caused by the first magnetic shield on the magnetic field.

10. The magnetic interference reduction device of claim 9, wherein the first magnetic shield comprises a continuous path of a high magnetic permeability material from a first edge of the first magnetic shield to a second edge of the first magnetic shield approximately in parallel to the direction of the magnetic field.

11. The magnetic interference reduction device of claim 10, wherein the high magnetic permeability material comprises a mu-metal and/or a nickel-iron alloy.

12. The magnetic interference reduction device of claim 10, comprising a second magnetic shield that is a planar magnetic shield and that is positioned approximately in parallel to the direction of the magnetic field, wherein the second magnetic shield is configured to reduce interference on the magnetic field along the direction of the magnetic field.

13. The magnetic interference reduction device of claim 12, wherein the first magnetic shield and the second magnetic shield are approximately parallel.

14. The magnetic interference reduction device of claim 12, wherein the cutout of the first magnetic shield comprises a linear portion that is parallel to the direction of the magnetic field and that divides the first magnetic shield into a first portion and a second portion and the cutout further comprises an open area portion between the first portion and the second portion.

15. The magnetic interference reduction device of claim 12, wherein the second magnetic shield comprises a cutout parallel to the direction of the magnetic field, the cutout is configured to reduce a distortion caused by the second magnetic shield on the magnetic field.

16. The magnetic interference reduction device of claim 12, wherein:
the first magnetic shield comprises:
a first shielding layer comprising the high magnetic permeability material;
a first foam layer covering the first shielding layer, the first foam layer configured to protect the first shielding layer by absorbing shock; and
a first metal layer configured to protect the first shielding layer; and
the second magnetic shield comprises:
a second shielding layer;
a second foam layer covering the second shielding layer, the second foam layer configured to protect the second shielding layer by absorbing shock; and
a second metal layer configured to protect the second foam layer.

17. A magnetic interference reduction device comprising:
one or more magnetic elements configured to generate a magnetic field;
a first planar magnetic shield positioned parallel to a direction of the magnetic field; and
a second planar magnetic shield positioned parallel to the direction of the magnetic field, wherein the first planar magnetic shield and the second planar magnetic shield are configured to reduce interference on the magnetic field along the direction of the magnetic field.

18. The magnetic interference reduction device of claim 17 wherein:
the first planar magnetic shield comprises a first cutout parallel to the direction of the magnetic field, the first cutout configured to reduce distortion caused by the first planar magnetic shield on the magnetic field; and
the second planar magnetic shield comprises a second cutout parallel to the direction of the magnetic field, the second cutout configured to reduce distortion caused by the second planar magnetic shield on the magnetic field.

19. The magnetic interference reduction device of claim 18, wherein:
the first planar magnetic shield comprises a first continuous path of a high magnetic permeability material from a first edge of the first planar magnetic shield to a second edge of the first planar magnetic shield approximately in parallel to the direction of the magnetic field; and
the second planar magnetic shield comprises a second continuous path of a high magnetic permeability material from a first edge of the second planar magnetic shield to a second edge of the second planar magnetic shield approximately in parallel to the direction of the magnetic field.

20. The magnetic interference reduction device of claim 17, wherein:
the first planar magnetic shield comprises:
a first shielding layer comprising a high magnetic permeability material;
a first foam layer covering the first shielding layer, the first foam layer configured to protect the first shielding layer by absorbing shock; and
a first metal layer configured to protect the first foam layer; and
the second planar magnetic shield comprises:
a second shielding layer;
a second foam layer covering the second shielding layer, the second foam layer configured to protect the second shielding layer by absorbing shock; and
a second metal layer configured to protect the second foam layer.
